(19) United States
(12) Patent Application Publication
(10) Pub. No.: US 2007/0108986 A1
(43) Pub. Date: May 17, 2007

(54) Systems and methods for performing differential measurements in an electrical system

(76) Inventors: Robert E. Moore, San Jose, CA (US); Kennebec M. Kious, Walnut Creek, CA (US)

Correspondence Address: JONES DAY, 222 East 41st Street, New York, NY, 10017-6702, US

(21) Appl. No.: 11/517,671

(22) Filed: Sep. 8, 2006

Related U.S. Application Data
(63) Continuation-in-part of application No. 11/281,283, filed on Nov. 17, 2005.

(51) Int. Cl. G01R 31/08; G08B 21/00

(52) U.S. Cl. 324/522; 340/657

(57) ABSTRACT

In accordance with the teachings described herein, systems and methods are provided for performing differential measurements in an electrical system. A first meter may be used that has a first time reference. A second meter may be used that has a second time reference, wherein the second time reference is synchronous with the first time reference. The first and second meters may be configured to use the first and second time references, respectively, to take time synchronized measurements of the electrical system. A processor may be used to receive the time synchronized measurements from the first and second meters and compare the time synchronized measurements to determine one or more electrical characteristics of the electrical system. The processor may also be used to correct for any existence time variation between the time synchronized measurements.

### FIELD

This technology relates generally to the measurement and analysis of electrical systems.

### BACKGROUND AND SUMMARY

The characteristics of an electrical system can often be better analyzed if measurements are available from multiple points within the system. For example, electrical characteristics of a component in a power distribution system (e.g., distribution impedance, power loss, power delivery efficiency, etc.) may be determined by comparing measurements taken at the source and load ends of the component. However, to accurately calculate a differential measurement in a dynamic system, the measurements being compared should be synchronous.

In accordance with the teachings described herein, systems and methods are provided for performing differential measurements in an electrical system. A first meter may be used that has a first time reference. A second meter may be used that has a second time reference, wherein the second time reference is synchronous with the first time reference. The first and second meters may be configured to use the first and second time references, respectively, to take time synchronized measurements of the electrical system. A processor may be used to receive the time synchronized measurements from the first and second meters and compare the time synchronized measurements to determine one or more electrical characteristics of the electrical system. The processor may also be used to correct for any existent time variation between the time synchronized measurements.

### BRIEF DESCRIPTION OF THE DRAWINGS

FIG. 1 is a block diagram illustrating an example measurement system for an electrical system.

FIG. 2 is a block diagram of an example method for synchronizing two or more meters for use in the measurement system of FIG. 1.

FIGS. 3A-3C illustrate an example of synchronizing two meters for use in the measurement system of FIG. 1.

FIGS. 4A and 4B illustrate an example of a cross-correlation to correct for a time difference in measurements taken by two meters.

FIGS. 5A and 5B illustrate an example use of the measurement system of FIG. 1 for calculating differential measurements in a typical three-phase power distribution system.

FIG. 6A illustrates an example use of the measurement system of FIG. 1 for calculating differential measurements across a load.

FIG. 6B illustrates an example use of the measurement system of FIG. 1 for comparing the electrical characteristics of various components in an electrical system.

FIG. 7 illustrates that the measurement system of FIG. 1 may also be used to determine higher order measurements.

FIG. 8 illustrates an example use of the measurement system of FIG. 1 for evaluating the performance of a distribution transformer or other electrical distribution equipment.

FIG. 9 illustrates an example use of the measurement system of FIG. 1 for evaluating the performance of components of a multi-stage transforming entity, such as an uninterruptible power supply (UPS).

### DETAILED DESCRIPTION

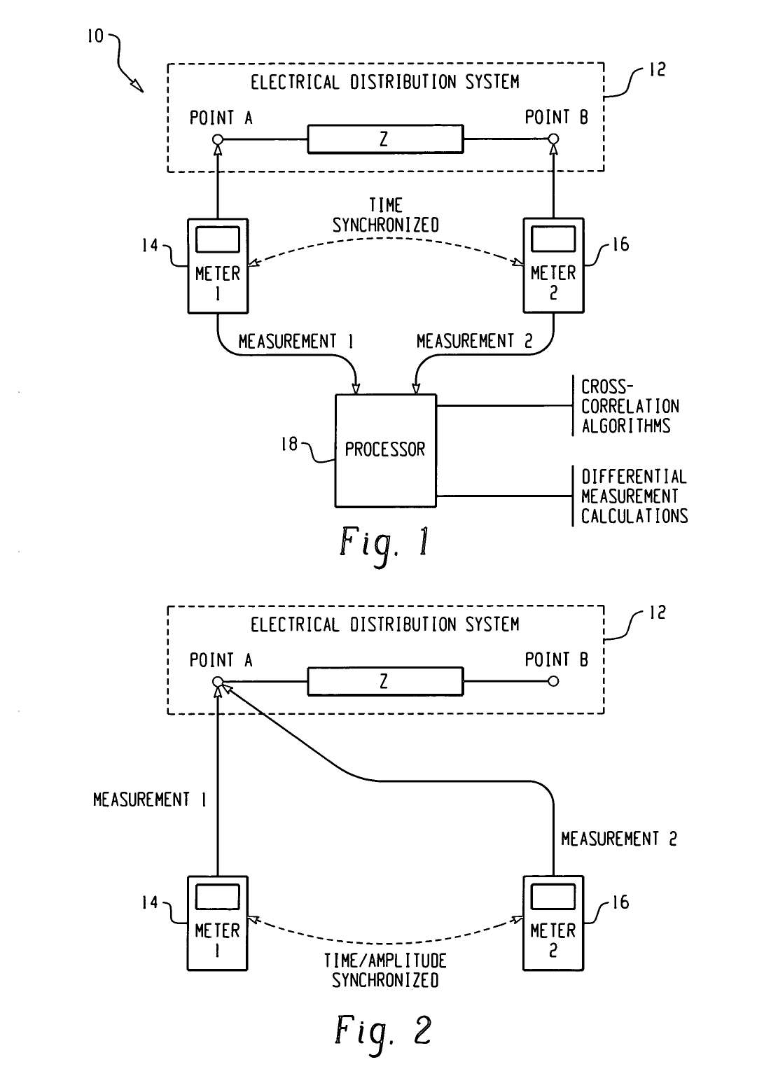

FIG. 1 is a block diagram illustrating an example system 10 for performing differential measurements in an electrical system 12. The system 10 includes a first meter 14 having a time reference (e.g., an internal clock) that is synchronized with a time reference for a second meter 16. The meters 14, 16 are both configured to take time synchronized measurements from the electrical system 12 and to communicate the measurements to a processor 18. The processor 18 compares the time synchronized measurements received from the meters 14, 16 to determine one or more electrical characteristics of the electrical system.

In the illustrated example, the first meter 14 is attached to one or more conductors at a first location (Point A) in an electrical distribution system 12. The second meter 16 is attached to the same conductor(s) at a second location (Point B) in the electrical distribution system 12. Time synchronized measurements are then taken at the two locations (Points A & B) by the respective meters 14, 16, and the measurements are provided to a processor 18. In addition, the measurements may be time referenced by including a time-stamp or other indication of the time at which the measurement was taken.

The processor 18 receives the measurements from the meters 14, 16 and performs differential calculations using the measurements to determine electrical parameters between the two locations (Points A & B) in the distribution system 12. For example, the processor 18 may use the measurements to determine the distribution impedance (Z), the voltage drop, the line current, the power loss, the power delivery efficiency, and/or other electrical parameters. Other, higher-order parameters may also be determined using the resultant differential measurements.

The processor 18 may be located remotely from the time synchronized meters 14, 16, as illustrated in FIG. 1. In this case, the meters 14, 16 may communicate with the processor 18 over a wired or wireless communication link. In another example, data may be transferred between the meters 14, 16 and the processor 18 using a memory card or other transferable data storage device. Also, in other examples the processor 18 may instead be resident in one or both of the meters 14, 16, and the meters 14, 16 may communicate with each other over a wired or wireless link or using a transferable data storage device. It should also be understood that other examples may include more than two meters and/or more than two measurement locations.

As illustrated in FIG. 2, the meters 14, 16 may be calibrated and time synchronized prior to being used to take differential measurements of the electrical system 12. In order to perform accurate differential measurements between physically separate locations in a dynamic system, the meters 14, 16 should be synchronized with reference to time and amplitude. The time references (e.g., internal clocks) in the meters 14, 16 are synchronized so that a time sequence of measurements that are to be compared may be performed at essentially the same time.

In one example, the time references for the meters 14, 16 may be synchronized by aligning a time reference, such as a clock, in each meter 14, 16 with a common trusted time reference. For instance, internal clocks in the meters 14, 16 may be aligned with an atomic clock, a satellite clock, the cycles of a synchronous waveform (e.g., a 60 Hz power transmission) or some other trusted time reference. In another example, the meters 14, 16 may use the 60 Hz cycles of a power distribution system as their time reference instead of utilizing an internal clock.

If the meters 14, 16 include time references that are sufficiently synchronized and that do not drift a meaningful amount during measurements, then no further time synchronization may be necessary. This may be the case if the meters 14, 16 include accurate clocks that are capable of being synchronized to a sufficiently fine resolution. In another example, sufficient time synchronization may be maintained between the meters by synchronizing them on an ongoing basis, for instance by receiving occasional precise synchronizing signals from an external signal (e.g., a satellite), or some other suitable means. If a sufficient level of time synchronization between the meters 14, 16 cannot otherwise be obtained, however, then the processor 18 may utilize cross-correlation algorithms to further time synchronize the measured data, as illustrated in FIG. 1.

With reference again to FIG. 1, the processor 18 may apply a cross-correlation algorithm to the time referenced measurements received from the meters 14, 16 to determine the amount of deviation between the time references. The data resultant from the cross-correlation may be a time difference value that is applied to the received measurement data to align the measurements in time. In this manner, accurate differential measurements may be provided by the processor 18 even if the time references in the meters 14, 16 are not perfectly synchronized.

The amplitudes of the measurements should also be calibrated so that measurements of the same signal at the same point in the system will be substantially identical on both meters 14, 16. If the amplitude calibrations of the meters 14, 16 are sufficiently accurate, and these calibrations do not drift by a meaningful amount, then no further amplitude synchronization may be necessary to perform differential calculations. This may be the case, for example, if very accurate meters are utilized that have been previously calibrated to a sufficiently fine resolution, such that the measurements of each meter 14, 16 are substantially identical. If this level of calibration is not present in the meters, however, then further amplitude synchronization may be performed.

As shown in FIG. 2, the measurement amplitudes may be synchronized by taking simultaneous measurements at the same point in the system 12 and having the resulting measurements cross-correlated with each other to determine the deviation between the amplitudes of similar measurements from each meter (e.g., voltage measurements and current measurements.) An amplitude correction factor determined by the cross-correlation may then be applied to one or both of the meters 14, 16 to adjust the amplitude of the measured data such that the measurement amplitudes of both meters 14, 16 are substantially the same. As an example, the following chart illustrates example measurements taken in a three-phase electrical distribution system by the meters 14, 16 shown in FIG. 2 and the resultant correction factors that are applied to synchronize the meters with respect to both time and amplitude.

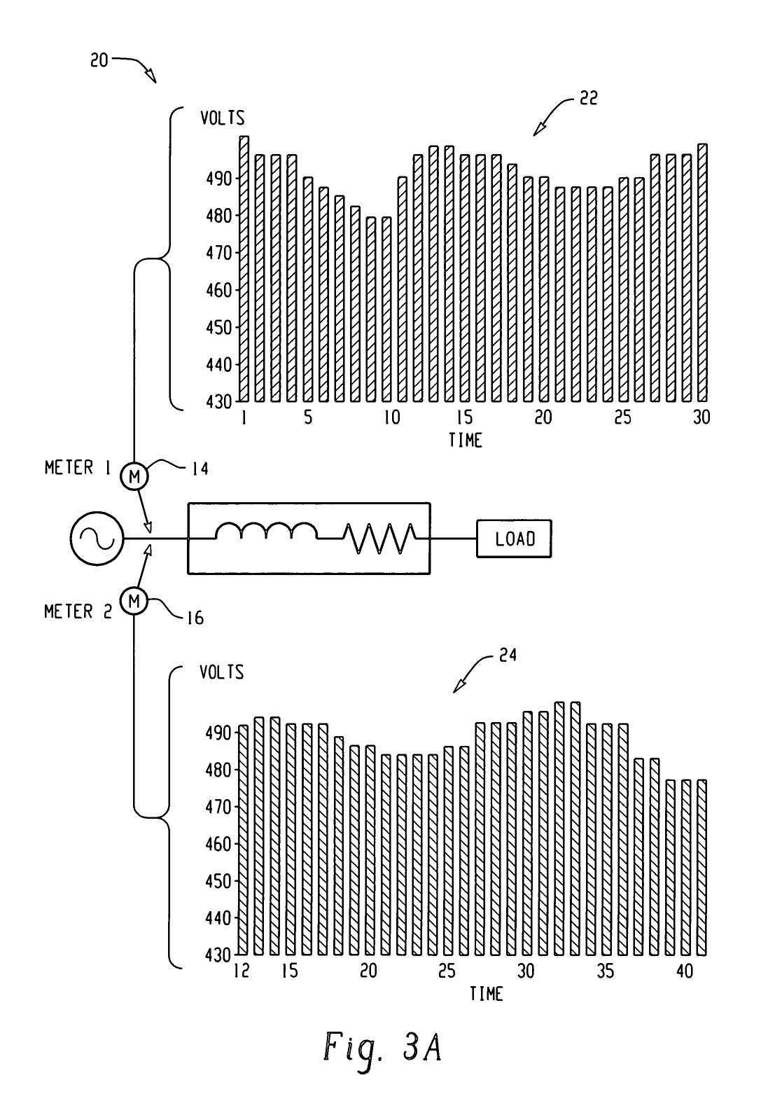

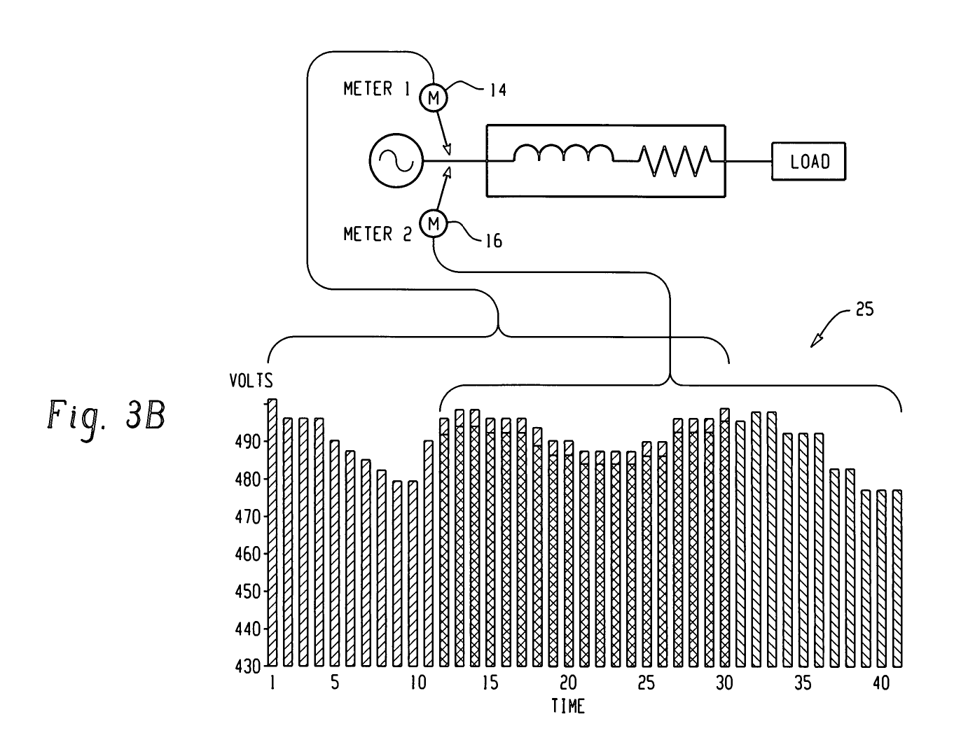

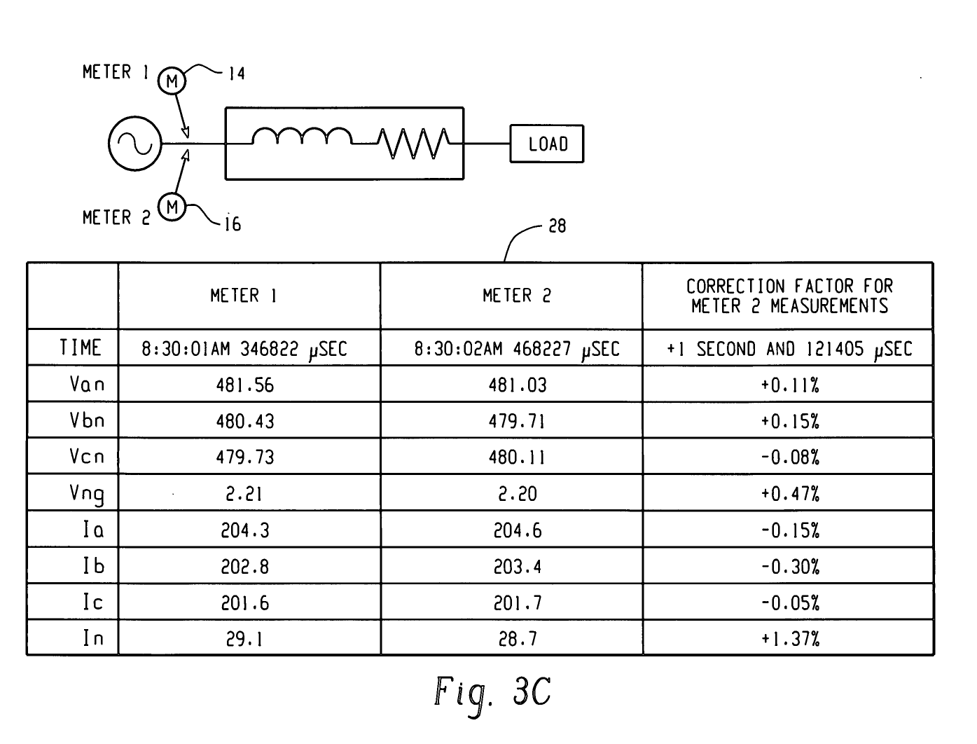

FIGS. 3A-3C illustrate a example initial time synchronization process. FIG. 3A shows two meters 14, 16 that are used to take a series of measurements (e.g., voltage measurements) at the same point in an electrical system 20. Graphs 22 and 24 illustrate the resultant measurements taken by the two meters 14 and 16, plotted with respect to a time reference. As shown, the initial measurements are not synchronized with respect to time. The measurements 22 taken by the first meter 14 begin at time reference 1 and the measurements 24 taken by the second meter begin at time reference 12. The graph 25 shown in FIG. 3B illustrates that when the second meter 16 is adjusted to compensate for the time variation, the measurements taken by the two meters become more closely aligned. To further synchronize the measurements in this example, however, the amplitude of the second meter 16 needs to be adjusted upward. FIG. 3C is a table illustrating example time and amplitude correction factors that may be applied to the second meter 16 in order to synchronize its measurements with those of the first meter 14.

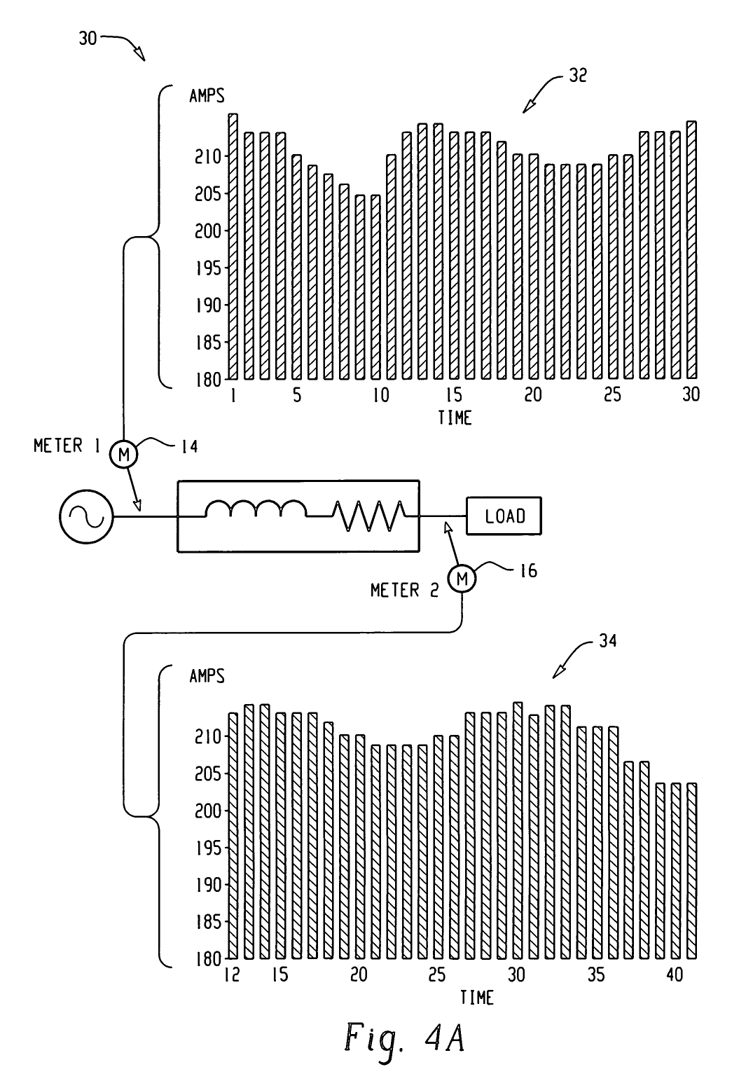

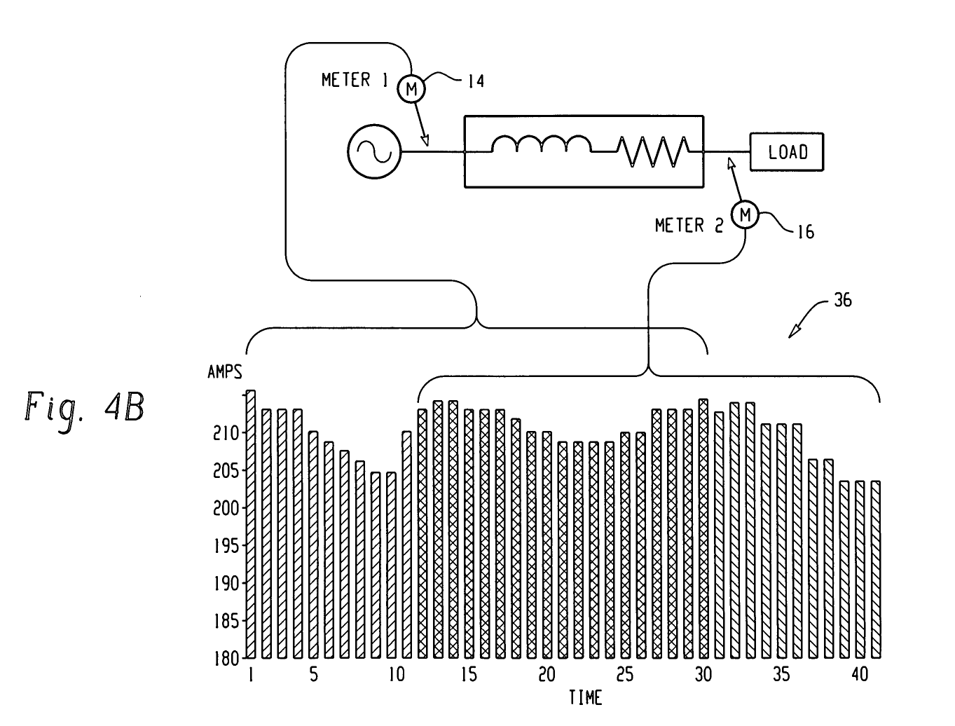

FIGS. 4A and 4B illustrate an example of a cross-correlation process to correct for a time difference in measurements taken by the two meters 16, 18. The two meters 14, 16 in this example are used to take a series of measurements (e.g., current measurements) at two different points in an electrical system 30. As explained above, cross-correlation algorithms may be applied to further time synchronize measured data if the initial time synchronization between the meters 14, 16 drifts by a significant amount. In this example, the measurements taken by the first and second meters 14, 16 are plotted with reference to time on graphs 32 and 34, respectively. As shown, the initial time synchronization has drifted by 12 time units in this illustrated example. The graph 36 shown in FIG. 4B illustrates that the data may be re-synchronized by cross-correlating the data to adjust for this time variation.

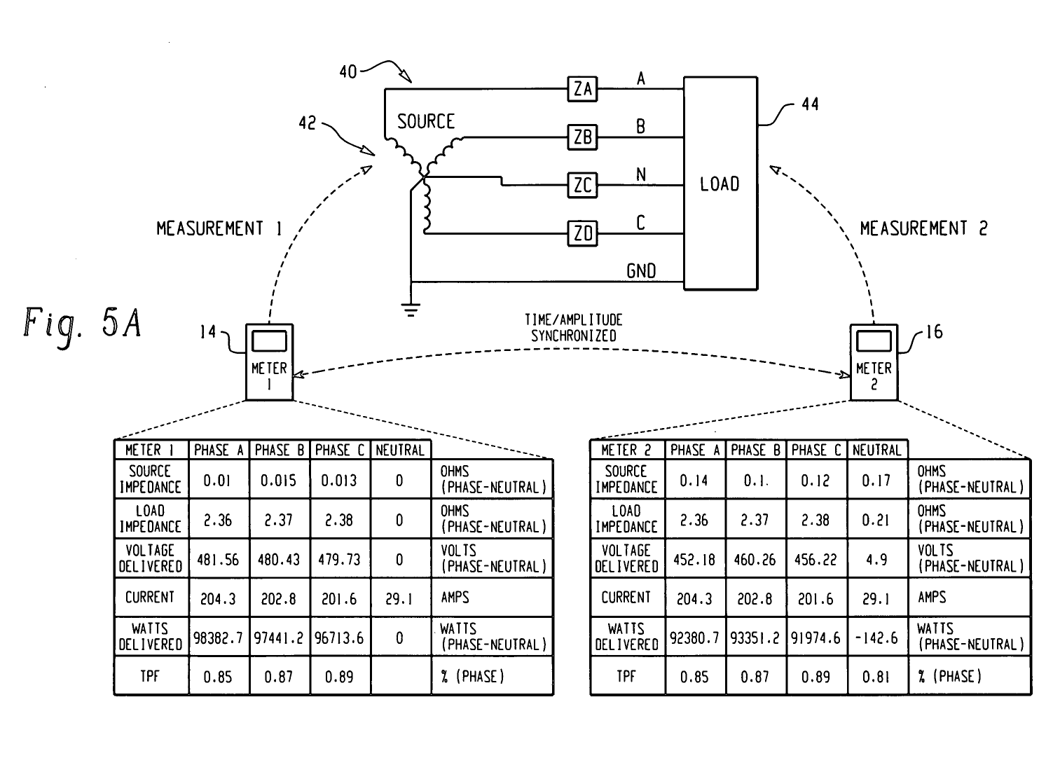

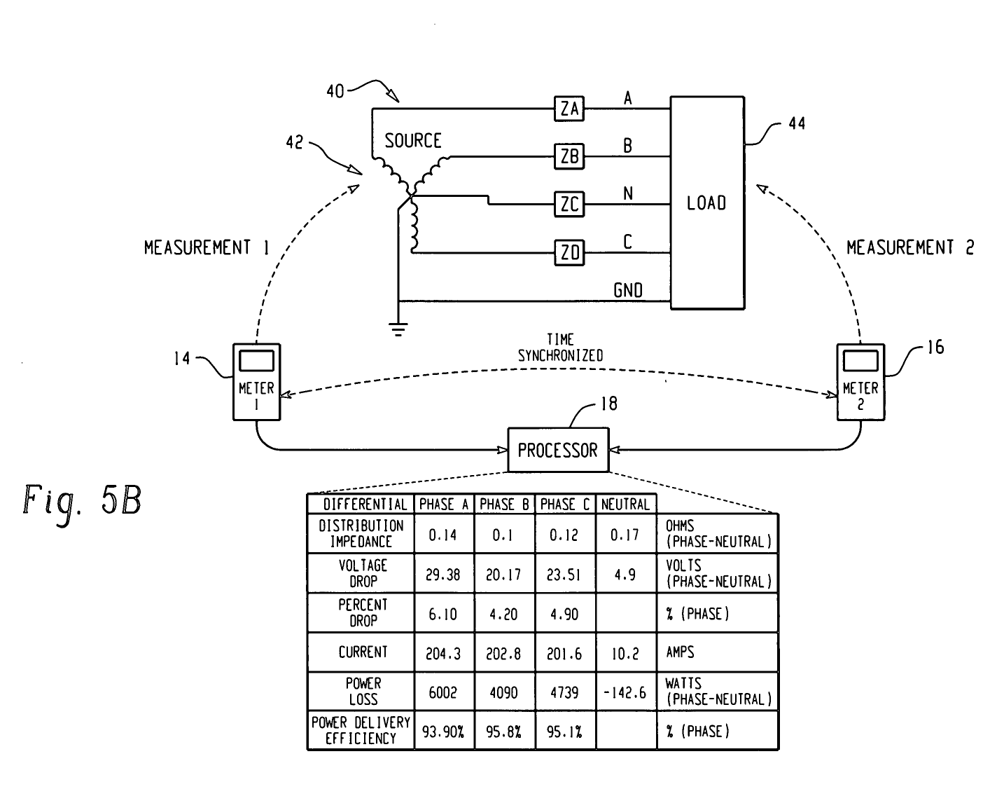

FIGS. 5A and 5B illustrate an example use of the measurement system of FIG. 1 for calculating differential measurements in a typical three-phase power distribution system. As illustrated in FIG. 5A, the synchronized meters 14, 16 may be used to take various time synchronized measurements at the source 42 and load 44, respectively. In the illustrated example, the first meter 14 is used to take measurements of the source impedance, load impedance, voltage delivered, current, watts delivered, and true power factor (TPF) at the source end of each transmission line (Z_{A}, Z_{B}, Z_{C} and Z_{D}). At substantially the same time, the second meter 16 is used to take measurements of the source impedance, load impedance, voltage received, current, watts consumed and TPF at the load end of each transmission line. As illustrated in FIG. 5B, the time synchronized measurements may be used by the processor to calculate differential measurements relating to the characteristics of the transmission lines (Z_{A}, Z_{B}, Z_{C} and Z_{D}). In the illustrated example, differential measurements are calculated for the distribution impedance, voltage drop, percent drop, current, power loss and power delivery efficiency in each line.

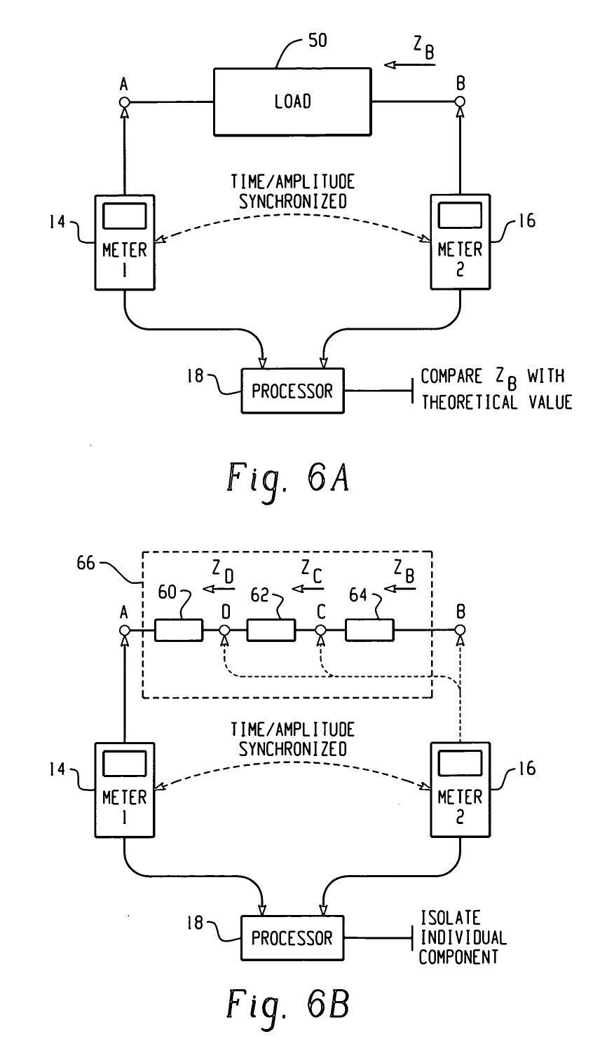

FIG. 6A illustrates an example use of the measurement system of FIG. 1 for calculating differential measurements across a load 50. The load 50 may, for example, be the distribution cable between two points (A and B) or may be some other component in an electrical system. One or more electrical characteristics of the load 50 may be determined by the processor 18 by comparing the time and amplitude synchronized measurements at points A and B. For example, the measurements may be compared to determine the load impedance (Z_{B}) and/or other load characteristics. The differential measurement(s) may then be compared with one or more expected values, for example to evaluate the operational performance of the load. For instance, the measured differential value(s) may be evaluated to determine if the load is operating at its expected efficiency, if the power loss across the load is at an expected value, if the load impedance is at an expected value, and/or other operational characteristics of the load.

FIG. 6B illustrates an example use of the measurement system of FIG. 1 for comparing the electrical characteristics of various components 60, 62, 64 in an electrical system 66. In this example, the first meter 14 is used to take measurements at a first point (Point A) in the electrical system 66. The second meter 16 is used to take measurements at points B, C and D in the system, substantially simultaneous with corresponding measurements taken at point A. The processor 18 uses the time and amplitude synchronized measurements to calculate differential measurements between points A and B, A and C, and A and D. In this manner, the differential measurements may be used to determine one or more electrical characteristics of each component 60, 62, 64 in the system 66. In one example, the differential measurements may be used to determine the impedance (Z_{B}, Z_{C}, Z_{D}) of each system component 60, 62, 64, for instance to isolate a faulty component.

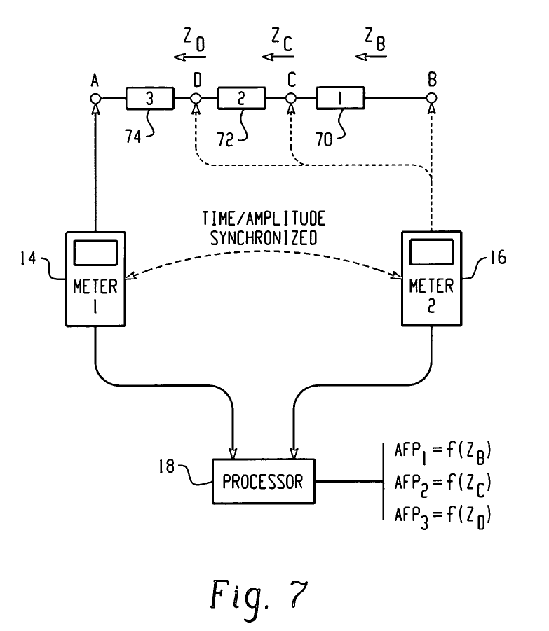

FIG. 7 illustrates that the measurement system of FIG. 1 may also be used to determine higher order measurements. In the illustrated example, the time and amplitude synchronized meters 14, 16 are used in combination with the processor 18 to determine differential measurements between point A and points B, C and D. The differential measurements are used to determine the impedance (Z_{B}, Z_{C}, Z_{D}) of multiple system components 70, 72, 74. The differential impedances (Z_{B}, Z_{C}, Z_{D}) are then used to calculate the X/R ratio to determine the arc flash potential (AFP) at each of the various points (A, B, and C) in the system. It should be understood that the measurement system may be used to determine higher order measurements, such as AFP, of any configuration of system components, including parallel loads. For instance, the impedance and resulting AFP may be determined for a combination of multiple system components, such as all of the components (1, 2 and 3) from point A to point B.

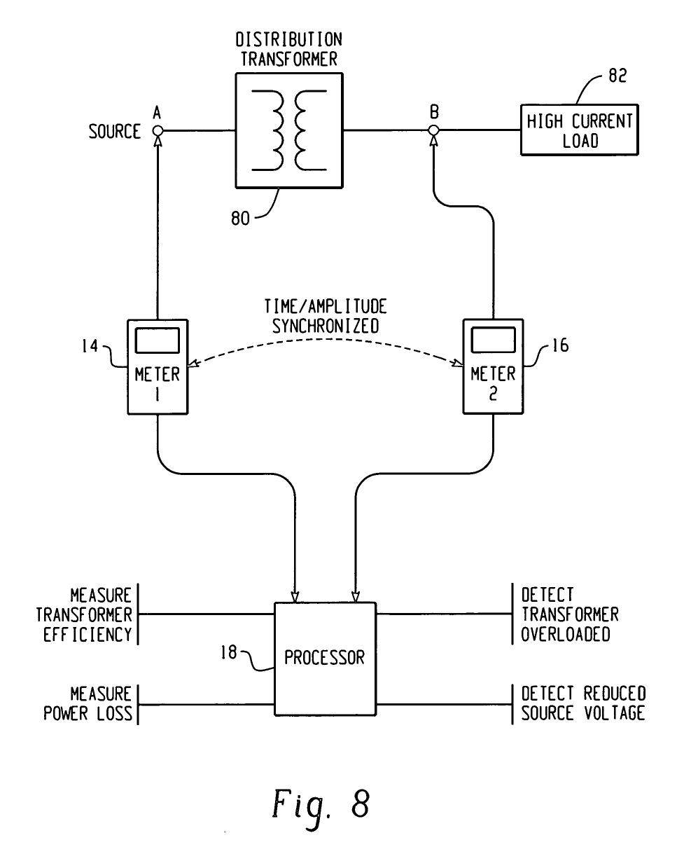

FIG. 8 illustrates another example use of the measurement system of FIG. 1 for evaluating the performance of a distribution transformer 80 or other electrical distribution equipment. When a high current load 82 is switched into a power distribution network, it may be difficult for the power distribution provider to determine if the sudden surge in current is resultant from the load or from a fault in the distribution system. For instance, medical facilities often operate high current equipment, such as magnetic resonance imaging (MRI) scanners. When this high current equipment 82 is activated, the large current draw from the power distribution system may appear similar to the current draw resulting from an equipment failure, such as an overloaded transformer.

As illustrated in FIG. 8, one or more differential measurements may be used to evaluate the performance of a power distribution component 80, such as a distribution transformer, under dynamic load. The differential measurements may, for example, be used to determine if an unexpected drop in the supplied power is resultant from a faulty transformer or from the inability of an underrated transformer to supply the necessary current to the load 82. For instance, the differential measurements may be used to determine if the transformer 80 is overloaded, incorrectly specified, or otherwise operating incorrectly. In other examples, other electrical characteristics of the power distribution component 80 may be determined, such as the transformer efficiency or power loss. It should be understood that similar measurements and calculations could also be performed for other power distribution components and/or other transforming entities, such as variable frequency drives or uninterruptible power supplies.

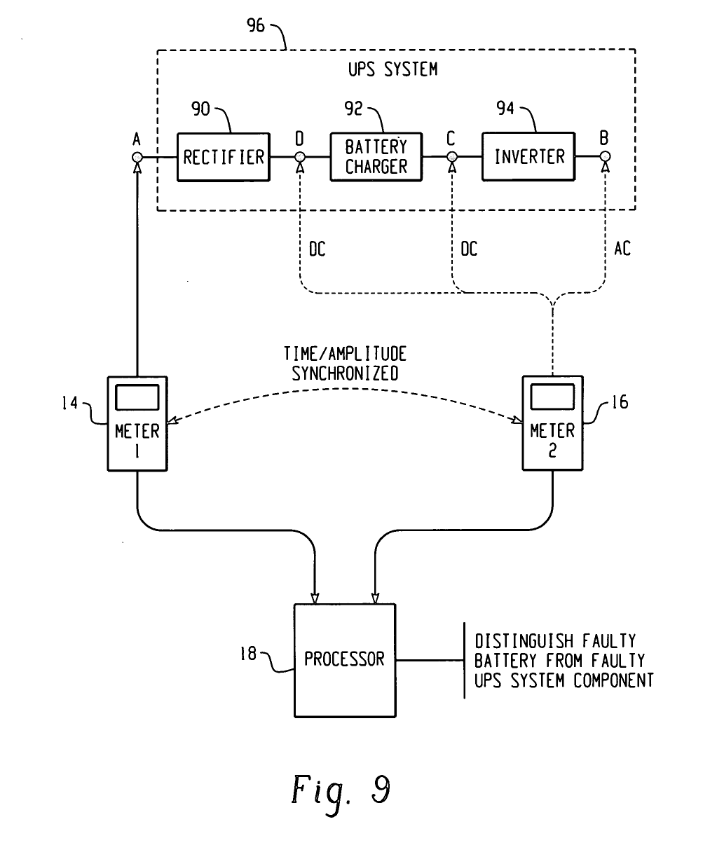

FIG. 9 illustrates an example use of the measurement system of FIG. 1 for evaluating the performance of components of a multi-stage transforming entity, such as an uninterruptible power supply (UPS). In this example, the first meter 14 is used to take measurements at a first point (Point A) in UPS system 96. The second meter 16 is used to take measurements at points B, C and D in the system, substantially simultaneous with corresponding measurements taken at point A. The processor 18 uses the time and amplitude synchronized measurements to calculate differential measurements between points A and B, A and C, and A and D. In this manner, the differential measurements may be used to determine one or more electrical characteristics of one or more individual component 90, 92, 94 in the system 96. In one example, this component-level data may be used to determine if a system failure is the result of one of the system components 90, 92, 94 malfunctioning or the result of a faulty battery.

This written description uses examples to disclose the invention, including the best mode, and also to enable a person skilled in the art to make and use the invention. The patentable scope of the invention may include other examples that occur to those skilled in the art.

It is claimed:

1. A system for performing differential measurements in an electrical system, comprising:
a first meter having a first time reference;
a second meter having a second time reference, the second time reference being synchronous with the first time reference;
the first and second meters being configured to use the first and second time references, respectively, to take time synchronized measurements of the electrical system; and
a processor that receives the time synchronized measurements from the first and second meters and compares the time synchronized measurements to determine one or more electrical characteristics of the electrical system,
the processor being further configured to correct for time variation between the time synchronized measurements.

2. The system of claim 1, wherein the first and second time references are internal clocks.

3. The system of claim 1, wherein the processor is located remotely from the first and second meter.

4. The system of claim 3, wherein the processor receives the time synchronized measurements over a wireless communication link.

5. The system of claim 3, wherein the processor receives the time synchronized measurements over a wired communication link.

6. The system of claim 3, wherein the processor receives the time synchronized measurements using one or more transferable data storage devices.

7. The system of claim 1, wherein the processor is resident in at least one of the first and second meters.

8. The system of claim 1, wherein the processor corrects for time variation by performing a cross-correlation function with respect to the time synchronized measurements.

9. The system of claim 1, wherein the time synchronized measurements each identify the time at which the time synchronized measurement was taken.

10. The system of claim 1, wherein the time synchronized measurements include at least one of impedance measurements, voltage measurements, current measurements or power measurements.

11. The system of claim 1, wherein the one or more electrical characteristics are compared with one or more expected values.

12. The system of claim 1, wherein the electrical system is a power distribution network.

13. The system of claim 1, wherein the time synchronized measurements are taken at multiple locations in the electrical system.

14. The system of claim 13, wherein the time synchronized measurements are used to identify one or more electrical characteristics of a plurality of component elements in the electrical system.

15. The system of claim 13, wherein the time synchronized measurements are used to identify a faulty component in the electrical system.

16. The system of claim 13, wherein the time synchronized measurements are used to identify arc flash potential at a plurality of locations in the electrical system.

17. The system of claim 13, wherein the electrical system is an uninterruptible power supply system.

18. The system of claim 1, wherein the time synchronized measurements are used to evaluate electrical characteristics of a power transforming component in the electrical system.

19. A method for measuring one or more electrical characteristics of an electrical system, comprising:
synchronizing a first time reference for a first meter with a second time reference for a second meter;
using the first meter to measure one or more electrical characteristics at a first point in the electrical system to generate a first time-synchronized measurement;
using the second meter to measure the one or more electrical characteristics at a second point in the electrical system to generate a second time-synchronized measurement;
transferring the first time-synchronized measurement and the second time-synchronized measurement to a processor;
correcting for any existent time variation between the first time-synchronized measurement and the second time-synchronized measurement; and
comparing the first time-synchronized measurement with the second time-synchronized measurement to determine a differential electrical characteristic between the first point and the second point in the electrical system.

20. The method of claim 19, wherein the correction of any existent time variation is performed using a cross-correlation function.

21. The method of claim 19, further comprising:
using the first meter to measure the one or more electrical characteristics at the first point in the electrical system to generate a third time-synchronized measurement
using the second meter to measure the one or more electrical characteristics at a third point in the electrical system to generate a fourth time-synchronized measurement;
transferring the third and fourth time-synchronized measurements to the processor;
comparing the third time-synchronized measurement with the fourth time-synchronized measurement to determine a second differential electrical characteristic; and
comparing the differential characteristic with the second differential characteristic to determine electrical characteristics of two or more components of the electrical system.

22. The method of claim 21, further comprising:
comparing the electrical characteristics of the two or more components to isolate a component of the electrical system that is not operating correctly.

23. The method of claim 21, further comprising:
using the electrical characteristics of the two or more components to determine an arc flash potential associated with each of the two or more components.

24. A measurement system for an electrical system, comprising:
a first meter having a first time reference;
a second meter having a second time reference, the second time reference being synchronous with the first time reference;
the first and second meters being configured to use the first and second time references, respectively, to take time synchronized measurements at two or more points in the electrical system.
means for correcting for any existent time variation between the time synchronized measurements; and
means for comparing the time synchronized measurements to determine one or more differential electrical characteristic between the two or more points in the electrical system.
